(19) United States
(12) Patent Application Publication
(10) Pub. No.: US 2013/0125819 A1
(43) Pub. Date: May 23, 2013

(54) CHEMICAL GAS DEPOSITION REACTOR

(71) Applicants: Christophe Borean, Le Touvet (FR); Jean-Luc Delcarri, St. Ismier (FR); Herve Monchoix, St. Ismier (FR); Thierry Remy, Vif (FR); Julien Vitello, Grenoble (FR)

(72) Inventors: Christophe Borean, Le Touvet (FR); Jean-Luc Delcarri, St. Ismier (FR); Herve Monchoix, St. Ismier (FR); Thierry Remy, Vif (FR); Julien Vitello, Grenoble (FR)

(73) Assignee: ALTATECH SEMICONDUCTOR, Montbonnot-Saint-Martin (FR)

(21) Appl. No.: 13/812,204

(22) PCT Filed: Jul. 11, 2011
(86) PCT No.: PCT/FR2011/000406

§ 371 Date: Jan. 25, 2013

(30) Foreign Application Priority Data
Jul. 26, 2010 (FR) 10/03120

(51) Int. Cl. C23C 16/455

(52) U.S. Cl. CPC C23C 16/455
USPC 118/725; 118/715

(57) ABSTRACT

The reactor includes: a chamber having a lower wall, an upper wall and a sidewall connecting the lower wall to the upper wall; a support plate mounted inside the chamber; at least one first supply line for a first gas, and at least one separate second supply line for a second gas; a gas injection device; and a gas collector. The gas injection device includes at least one injector connected to the first supply line and at least one injector connected to the second supply line, the injectors leading into the chamber through at least one inlet provided in the sidewall; all of the injectors of the first supply line and all of the injectors of the second supply line are connected one above the other; and the collector includes at least one outlet in the sidewall, opposite the inlet relative to the support plate, and substantially at the inlet.

In general, the invention relates to methods of chemical gas deposition, often known in the art as chemical vapour deposition or CVD.

In accordance with CVD methods, gaseous materials, known as precursors, react on the surface of a substrate to form one or a plurality of, generally very thin, layers of product.

In a non-limiting manner, the invention comes within the scope of CVD methods in which the precursors are of metal-organic type. The term MOCVD (metal-organic chemical vapour deposition) is generally used for these particular methods.

MOCVD methods are used in particular in the production of semiconductor devices of the III-V type.

These III-V semiconductors are widely used in electronic and optoelectronic devices, such as high electron mobility field effect transistors (HEMFET), high brightness light-emitting diodes (LEDs) or laser diodes (LDs).

The invention relates more particularly to the production of semiconductors of the “gallium nitride” or GaN type. GaN semiconductors of the semiconductor family of the III-V type are the most widely manufactured at present because of their applications in short-wavelength LEDs and LDs. It will be appreciated, however, that the invention is not limited to this particular application.

In this particular application, the MOCVD method also enables the combined use of gallium (Ga) and one or a plurality of further elements from group III of Mendeleev's periodic table, such as aluminium (Al) or indium (In). Thin layers of alloy may thus be produced and are currently used in heterogeneous structures for use in LEDs.

In general, improving productivity as regards semiconductor devices makes it necessary to apply MOCVD methods both to very large substrates and/or multiple substrates which may be of a much smaller size.

In both cases, a batch production tool known as a “reactor” is used. A reactor comprises what is known in the art as a “susceptor”, i.e. a support for the substrate(s) housed in a chamber. One or more chemical agents in gaseous phase are caused to circulate in this chamber so that the flow of material “sweeps” the substrate.

For the production of GaN semiconductors, use is chiefly made of substrates of crystalline sapphire (Al₂0₃) or silicon carbide (SiC). Up to now, however, it has not been possible, or it is very difficult, to produce substrates of a sufficiently large size. In practice, the sizes currently produced are of 2 and 4 inches in diameter.

To improve productivity, it is therefore preferred to use high-load reactors, in which a plurality of substrates are simultaneously loaded in the form of a thin plate, known in the art as a “wafer”.

To ensure the high-quality performance of the semiconductors produced, it is essential for the thickness of the GaN layer and/or the composition of the heterogeneous structures to be very carefully monitored. Producing a uniform layer in particular involves the gaseous agents flowing in a laminar manner over the whole extent of the wafer substrates.

In addition, the MOCVD—GaN method must take place in pressure conditions—of the magnitude of several hundred Torr—such that certain of the gases may react with one another to form solid particles on/in the layer being formed. This is particularly true of gallium nitride (GaN) and those precursors which comprise nitrogen (N), for instance ammonia. The same problem may arise with aluminium-gallium nitrides (AlGaN) and indium-gallium nitrides (InGaN).

As well as worsening the performance of the semiconductors produced, these problems, which cannot be controlled or replicated, produce batches of uneven quality.

Lastly, it may be that the chemical agents are deposited on the walls of the reactor chamber: the thermal emission characteristics are then locally modified/altered. The thermal environment in the chamber then lacks homogeneity and, ultimately, the semiconductors produced may have performance characteristics that potentially differ from one another.

The invention seeks to improve the situation.

The invention relates to a reactor comprising:
a chamber having a lower wall, an upper wall and a side wall connecting the lower wall (15) to the upper wall;
a support plate for one or more substrate elements which is mounted inside the chamber;
at least one first supply line for a first type of gas, and at least one second supply line, separate from the first supply line, for a second type of gas;
a gas injection device and a gas collector.

In the reactor:
the gas injection device includes at least one injector connected to the first supply line and at least one injector connected to the second supply line, said injectors leading into the chamber through at least one inlet provided in the side wall;
all of the injectors of the first supply line and all of the injectors of the second supply line lead into the chamber one above the other;
the collector includes at least one outlet provided in the side wall at a location opposite said inlet relative to the support plate and substantially at the level of said inlet.

The proposed reactor makes it possible to obtain laminar gas flows at a wide range of pressures and temperatures, including in a large reactor of the batch reactor type. The gas flows are in particular laminar above all the substrates disposed on the support plate. The speed range of these flows is also substantially uniform over the whole of the surface of said support plate so that the various layers of material have a high degree of uniformity.

The proposed reactor may also prevent undesired chemical reactions between elements in the gaseous phase. It makes it possible in particular to separate the alkyl hydride(s) from the other gases to be reacted. The precursors of column III of the periodic table may in particular be separated from those of column V.

Further features and advantages of the invention are set out in the following detailed description and in the accompanying drawings, in which:

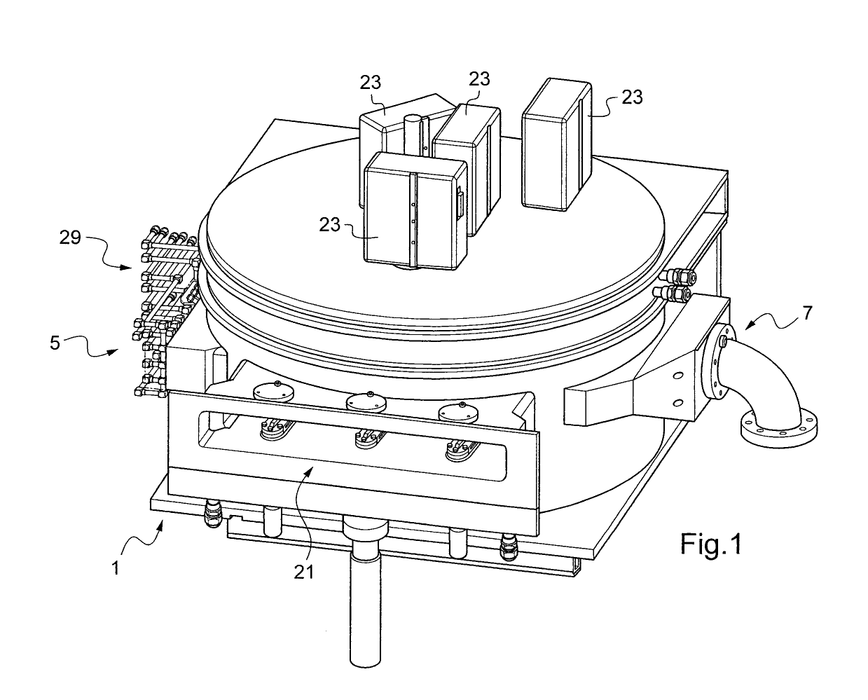

FIG. 1 is a perspective view of a CVD reactor;

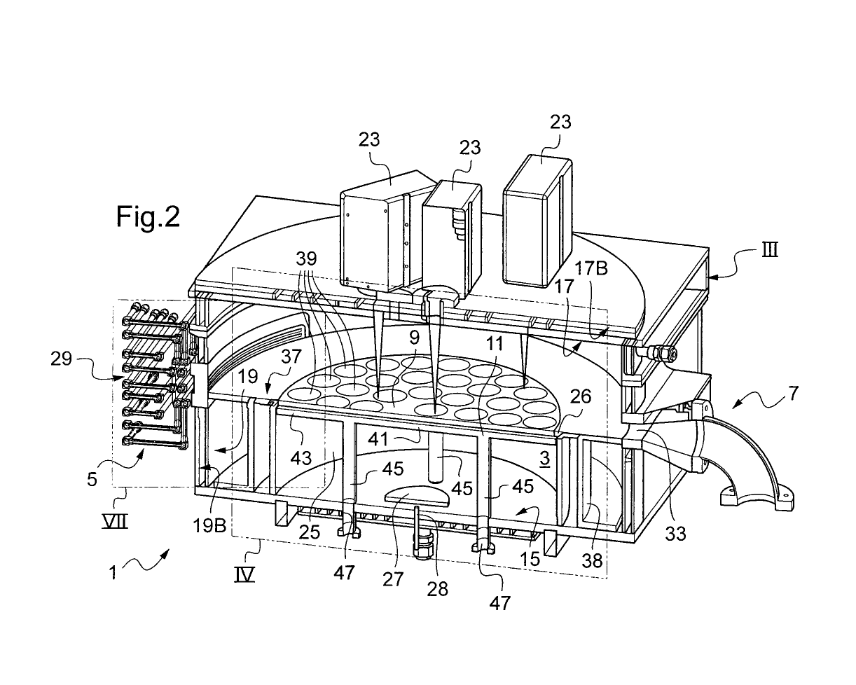

FIG. 2 shows the reactor of FIG. 1 in section along a median vertical plane;

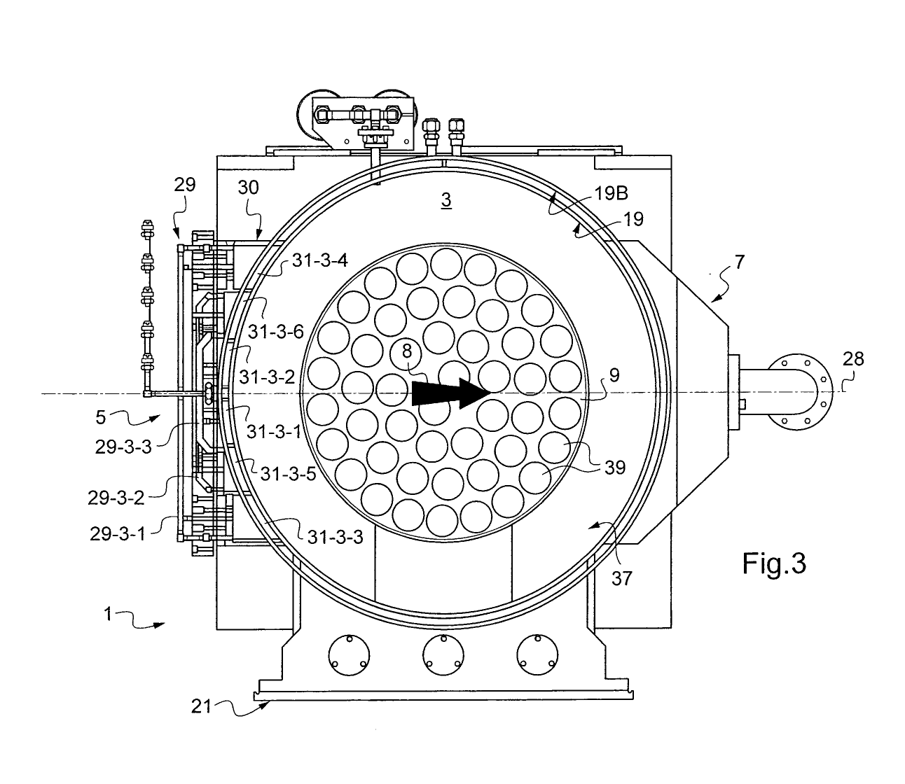

FIG. 3 is a plan view of the reactor of FIG. 1 in section along a horizontal plane passing through a point III of FIG. 2;

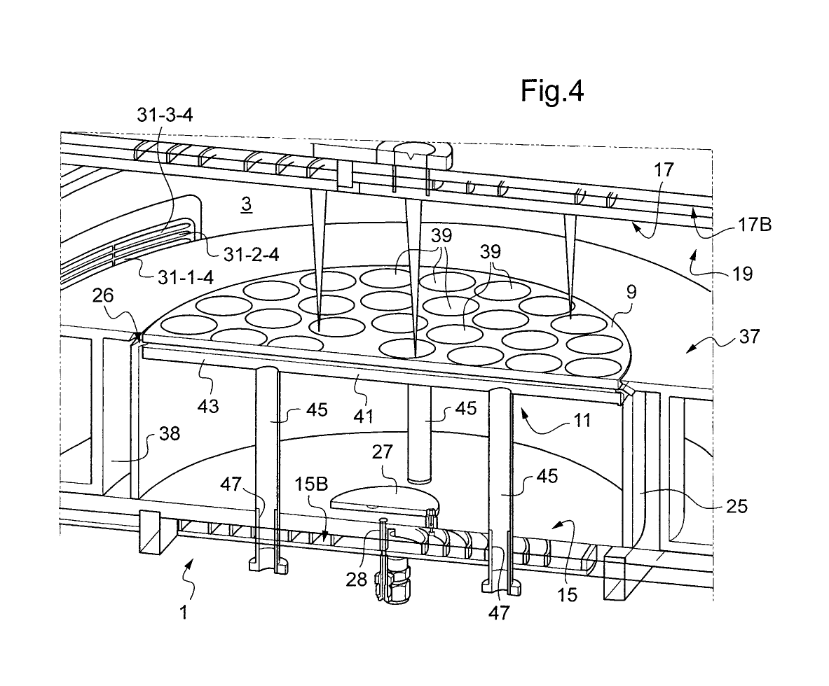

FIG. 4 shows a detail IV of FIG. 2;

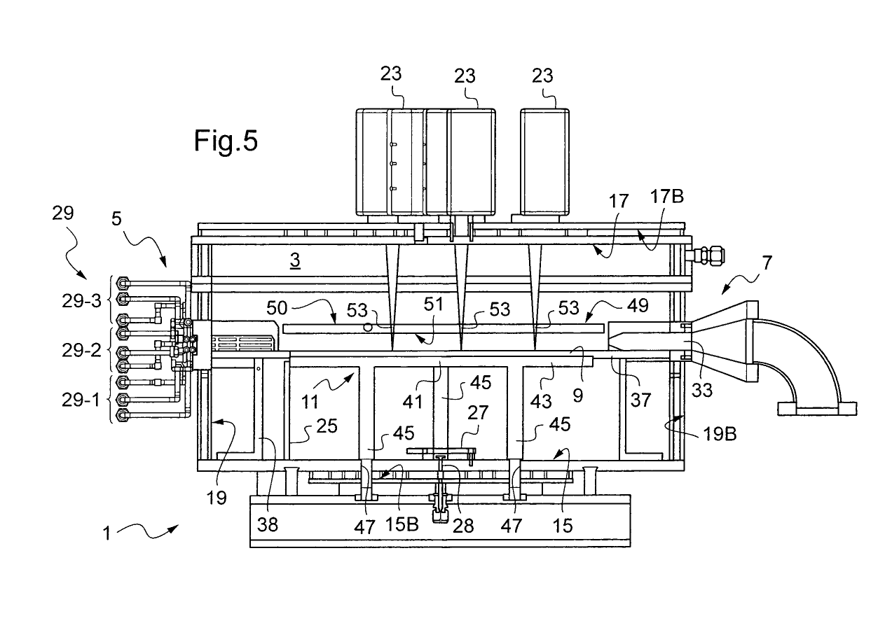

FIG. 5 is similar to FIG. 2, showing a plan view of the reactor;

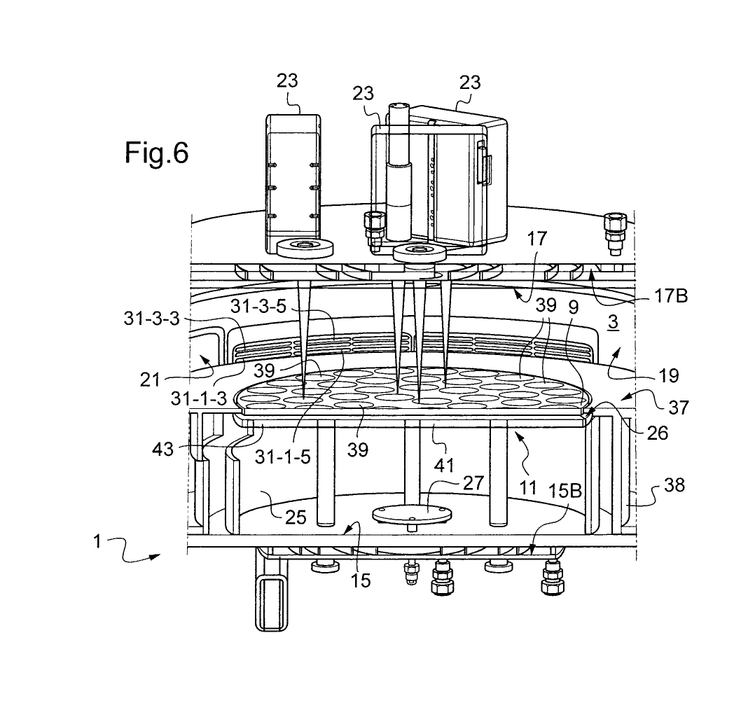

FIG. 6 shows a part of the reactor of FIG. 1 in section along a vertical plane perpendicular to the sectional plane of FIG. 2;

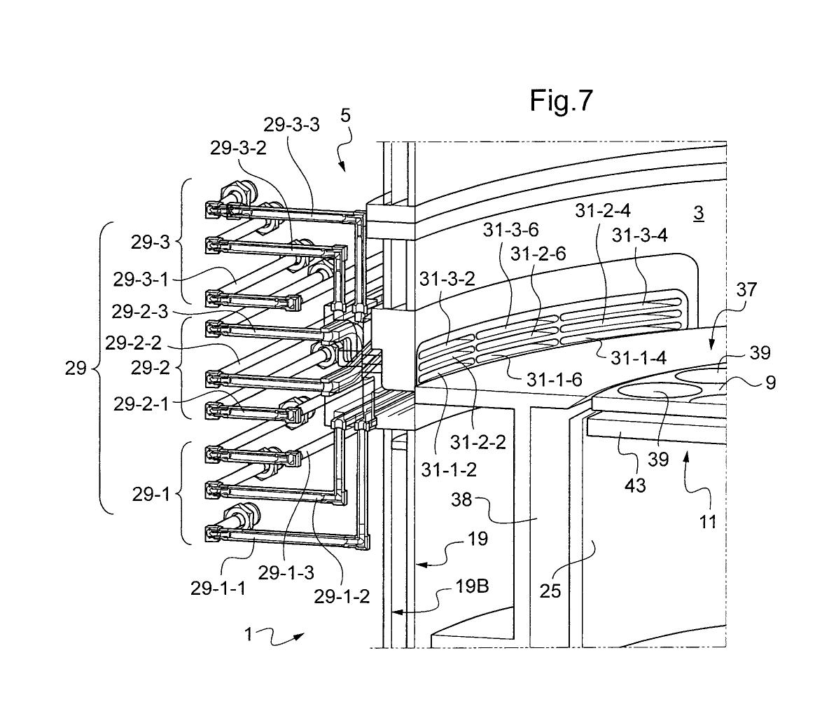

FIG. 7 shows a detail VII of FIG. 2.

The accompanying drawings comprise definite members. They may therefore not just supplement the invention but also help, where necessary, to define it.

The drawings, in particular FIGS. 1, 2, 3 and 5, show a reactor 1 for depositing gaseous chemical agents.

The reactor 1 comprises a chamber 3, an injection device 5 for gaseous chemical agents which leads into the chamber 3 and a collector 7 for the chemical agents in the chamber 3.

The reactor 1 further comprises what is known in the art as a susceptor 9 mounted inside the chamber 3.

The susceptor 9 is intended to support one or a plurality of substrates, possibly in the form of a wafer comprising a plurality of substrates, on which the deposition of elements in the gaseous state is to be initiated in the chamber 3.

The susceptor 9 is formed as a plate and is, in this case, disc-shaped.

The injection device 5 and the collector 7 are disposed with respect to one another such that a gas flow shown by the arrow 8 is generated in the chamber 3 (FIG. 3) from the injection device 5 to the collector 7, whose path passes via the susceptor 9, above the latter and flush with the upper surface of the susceptor 9.

In this case, the injection device 5 and the collector 7 are generally opposite one another with respect to the centre of the susceptor 9.

The reactor 1 further comprises a device for heating the susceptor 9 which is designated generally by reference numeral 11 in the drawings. The heating device is disposed below the susceptor 9 in the chamber 3.

The chamber 3 is bounded by a lower wall 15, an upper wall 17 and a side wall 19 which connects the lower wall 15 to the upper wall 17.

The chamber 3 has the form in this case of a cylinder of circular section. In other words, the lower wall 15 and the upper wall 17 have a similar development, in the general shape of a disc, while the side wall 19 connects the peripheral edge of the lower wall 15 to the peripheral edge of the upper wall 17. The contour of the side wall 19 thus has a shape corresponding to the contour of the susceptor 9.

The lower wall 15, upper wall 17 and side wall 19 and, more generally, most of the components which are housed, at least partially, in the chamber 3 are made, where possible, from stainless steel, preferably of 316L type.

A slot opening 21 enters the chamber 3 via the side wall 19. This slot opening 21 is shaped so as to enable the susceptor 9 to be inserted into and removed from the chamber 3.

The upper wall 17 has at least one window (not shown) through which optical monitoring instruments, shown in general by 23, may work.

These instruments 23 in particular monitor the temperature of the substrates and the reflectance of the surfaces deposited. The temperature of the susceptor 9 and the growth of the various layers, especially in the case of heterogeneous structures, is thus monitored.

The reactor 1 further comprises a member acting as a support for the susceptor 9, or “susceptor-holder” 25, which is mounted in the chamber 3 such that it can rotate with respect thereto about an axis extending heightwise in the chamber 3. In this case, the axis of rotation passes in practice through the centre of the susceptor 9.

The susceptor-holder 25 has the general shape of a hollow cylinder portion, one end of which rests on the lower wall 25, in a centred manner with respect thereto, while the opposite end supports the susceptor 9. The inner diameter of the susceptor-holder 25 is substantially greater than the diameter of the susceptor 9 making it possible to house the heating device 11 within the hollow cylinder. In the vicinity of its end bearing the susceptor 9, the cylinder forming the susceptor-holder 25 has a thinner section so as to provide an end edge 26 which supports the lower surface of the susceptor 9 on an edge portion.

The susceptor-holder 25 may be magnetically coupled to a drive device (not shown) disposed outside the chamber 3 for driving it via the lower wall 15, for instance. The rotation of the susceptor 9 makes it possible to obtain an homogeneous temperature on its surface.

Advantageously, the drive device is able to cause the susceptor-holder 25 to pivot at a speed of between 1 and 200 revolutions per minute. This speed of rotation is set as a function of the speed of the flow of the gases on the susceptor 9, the diameter of the substrate(s) and the required/desired speed of deposition.

The lower wall 15, the upper wall 17 and the side wall 19 are each cooled by means of one or a plurality of cooling devices (not shown) able to keep the temperature of these walls below 60° C.

In this case, the lower wall 15, the upper wall 17 and the side wall 19 are all at least partially lined with a respective wall, i.e. a lower lining wall 15B, an upper lining wall 17B and a side lining wall 19B. In each case, one or a plurality of ducts (not shown) designed to circulate a cooling fluid, shaped for instance as coils, may be housed in the space separating a wall from its lining wall in order to cool said wall.

As an alternative, or as a supplement, ducts designed to circulate cooling fluid may be provided in the thickness of the upper wall 15, lower wall 17 and side wall 19.

The cooling of the walls bounding the chamber 3 minimises the deposition of III-V elements on these walls. The time needed to clean the chamber 3 is thereby reduced which, in turn, also improves the productivity of the reactor 1.

A diffuser 27, formed as a disc-shaped plate, may be disposed in the chamber 3 in the vicinity of the lower wall 15 and in a centred manner with respect to and below the susceptor 9. The diffuser 27 makes it possible to diffuse a neutral gas, of the type of argon (Ar) for instance, in an homogeneous manner below the susceptor 9.

It can be seen from FIG. 4 in particular that an exhaust opening 28 may be provided through the lower wall 15, below the susceptor 9, and in this case below the diffuser 27. This prevents the gases flowing below the susceptor 9 from reacting and forming deposits thereon.

During the growth process of an heterogeneous structure or of a III-V material, the reaction gases flow over the substrate and the surfaces of the susceptor 9, from the injection device 5 to the collector 7. The flow of gas is essentially parallel to the surfaces of the substrate and the susceptor 9 and is laminar in nature. This ensures a uniform thickness of deposition for all the substrates supported on the susceptor 9.

Optionally, a convection restrictor, which will be described in further detail below, may be disposed in the chamber 3 to prevent, or at least limit, any convection phenomena in the gases to be deposited when they pass above the upper surface of the susceptor 9.

The injection device 5 will now be described in detail with particular reference to FIGS. 3, 5, 6 and 7.

The injection device 5 comprises a plurality of gas supply lines, shown in general by 29. Each supply line 29 is intended to convey a gas of a certain type.

The set of supply lines 29 comprises:
a first sub-set 29-1 formed by supply lines intended to convey a gas of a first type, for instance nitrogen (NH₃);
a second sub-set 29-2 formed by supply lines intended to convey a gas of a second type, for instance a precursor from column III of the periodic table (Alkyl);
a third sub-set 29-3 formed by supply lines intended to convey a gas of a third type, for instance a mixture of dinitrogen (N₂) and dihydrogen (H₂).

Each supply line 29 is connected to one or a plurality of injectors, shown generally by 30, which lead into the chamber 3 via one or a plurality of inlets provided in the side wall 19 and shown generally by 31.

The injectors 30 connected to the supply lines 29 belonging to the same sub-set are disposed so that they lead into the chamber substantially in a common plane, parallel to the general plane of the susceptor 9. In other words, all the injectors 30 connected to the supply lines 29 of the same sub-set lead into the chamber 3 at the same level.

The planes common to the various sub-sets of supply lines 29 are superimposed on one another.

In other words, the supply lines 29 lead into the chamber 3 at different levels (heights) of said chamber depending on the type of gas that they convey.

The supply lines of the first sub-set 29-1 may be termed “lower lines”, those of the second sub-set 29-2 may be termed “median lines” and those of the third sub-set 29-3 may be termed “upper lines”.

The injectors 30 connected to the upper supply lines 29-3-1, 29-3-2 and 29-3-3 inject a layer of gas which acts as a confining layer for the alkyl and ammonia, thus promoting the dispersion of the former in the latter in the direction of the surface of the substrate.

The injectors 30 connected to the same supply line 29 are in each case distributed symmetrically with respect to a diameter of the susceptor 9. Each supply line thus leads into the chamber on either side of this diameter and communicates with different and symmetrical portions of the surface of the susceptor 9.

The diameter of the susceptor 9 which forms the axis of symmetry for the arrangement of the injectors 30 connected to a same supply line 29 is common to all the injectors 30 connected to the various supply lines 29. This axis of symmetry is shown by 28 (FIG. 3).

It is preferable to connect an even number of injectors 30 to a same supply line 29 with a view to symmetry. Each supply line 29 is in this case connected, for instance, to two injectors 30.

Again by way of example, each sub-set 29-i has three supply lines 29-1-1, 29-1-2 and 29-1-3 (i being a whole number between 1 and 3).

All the injectors 30 connected to the supply lines 29-1-1, 29-1-2 and 29-1-3 of the first sub-set 29-1 lead into the chamber above all the injectors 30 connected to the supply lines 29-2-1, 29-2-2 and 29-2-3 of the second sub-set 29-2. All the injectors 30 connected to the supply lines 29-3-1, 29-3-2 and 29-3-3 of the third sub-set 29-3 lead into the chamber above all the injectors 30 connected to the supply lines 29-2-1, 29-2-2 and 29-2-3 of the second sub-set 29-2.

Each sub-set 29-i of supply lines then has six injection zones each corresponding to an injector. Each gas flow is thus distributed over the whole of the surface of the susceptor 9 symmetrically with respect to the axis 28.

Each sub-set of supply lines 29-i thus corresponds to a central injection zone, comprising the injectors close to the axis 28, a peripheral injection zone, comprising the injectors remote from the axis 28, and an intermediate injection zone, between the central zone and the peripheral zone, comprising the injectors interposed between the injectors of the central zone and the injectors of the peripheral zone respectively.

Each supply line 29 is associated with a mass flow controller (not shown) able to ensure accurate mixing of the flows and laminar flow conditions in the chamber 3.

The flow in each of the supply lines 29 may thus be controlled independently from the flow in the other lines 29. Laminar flow conditions may be ensured, while in practice preventing any parasitic gaseous phase reactions.

The injectors 30 corresponding to the lower supply lines 29-1 lead into the chamber above the upper surface of the substrate, preferably substantially at the level of the upper surface of the substrate, flush with said surface.

The distribution of the various supply lines 29, and their respective injectors 30, over the height of the chamber 3, and the distribution of the various precursors in the respective supply lines 29 leads to a physical separation of the injectors 30 minimising gaseous phase reactions.

Several inlets are provided in the lateral wall 19. Each injector 30 leads into the chamber 3 via one of these inlets.

In this case, each injector 30 is formed by at least a portion of an injection passage 31 and the end of a respective supply line communicating with the passage in question. Each injection passage 31 is terminated by an inlet of the side wall 19. In this case, each injection passage 31 has a flared shape from the point at which a respective supply line leads into the inlet. Each injection passage forms what may be called a “diffuser cone”.

Each injector 30 may be seen as an injection nozzle. The injectors 30 may also be produced in a form differing from what is described here. It may be envisaged, in particular, to make the ends of at least some of the supply lines lead directly into the chamber 3 via an inlet provided in the side wall 19, thus providing an injector which lacks what has been described here as an injection passage 31. Moreover, the operative injection and diffusion members could be integrated in the injectors 30, for instance interposed between one end of a respective supply line and the corresponding injection passage 31. Where appropriate, a passage 31 could be common to a plurality of injectors.

The injection passages 31 are disposed to correspond with the injectors 30.

Each injection passage 31 extends transversely over an angular sector of the chamber 3 making it possible optimally to distribute the gas flow over a targeted portion of the susceptor 9.

In FIG. 7, for instance, the injection line 29-1-3 leads into the chamber 3 via a passage 31-1-2 close to the axis 28 (and via a passage, not shown in FIG. 7, symmetrical with the passage 31-1-2 with respect to the axis 28), the injection line 29-1-1 via a passage 31-1-4 remote from the axis 28, and the injection line 29-1-2 via a passage 31-1-6 disposed at the same level as and between the passages 31-1-2 and 31-1-4. The injection line 29-2-2 leads into the chamber 3 via a passage 31-2-6 disposed above the passage 31-1-6 corresponding to the injection line 29-1-2. These passages 31-1-6 and 31-2-6 are also shaped in a similar manner to one another. The same applies to the passage 31-3-6 which corresponds to the supply line 29-3-2. In the same way, the position and the shape of the passages 31-2-2 and 31-3-2 corresponding respectively to the supply lines 29-2-3 and 29-3-3, on the one hand, and the passages 31-2-4 and 31-3-4 corresponding respectively to the supply lines 29-2-1 and 29-3-1, on the other hand, can be deduced from the above description of the passages 31-1-6, 31-2-6 and 31-3-6.

The collector 7 in this case comprises an outlet 33, or suction opening, provided in the side wall 19 at a location opposite the injection passages 31 with respect to the susceptor 9.

As a variant, the collector 7 may be provided with a plurality of outlets, for instance an outlet for each sub-set of supply lines 29. In this case, each outlet may extend so as to cover an angular sector of the side wall 19 corresponding to the projection, on this wall, of the diameter of the susceptor 9 and, in terms of height, to a gas flow thickness. The collector 7 could also have an opening corresponding, in terms of shape and/or position, to each of the passages 31 of the injection device 5.

In other words, the collector 7 could comprise a plurality of gas suction outlets, each being disposed opposite a gas injection inlet of the injection device 5. This could make it possible further to improve the laminar flow of the various gases over the susceptor 9.

A jacket 37, in the form of an annular crown, is disposed in the chamber 3 so as to fill the space extending radially between the side wall 19 and the peripheral edge of the susceptor 9 at the level of the upper surface of said susceptor 9.

In this case, the jacket 37 has a radial extension of a few centimetres.

The jacket 37 has an upper surface disposed at the level of both the base of the injectors 30 connected to the lower supply lines 29-1 and the upper surface of the susceptor 9.

The jacket 37 forms a zone in which the precursor gases, supplied at a temperature lower than the temperature of the growth process, are heated before they reach the susceptor 9 and are deposited on the substrate(s).

The jacket 37 also provides a zone in which the flow of precursors may be established in a laminar manner. This provides the growth process with greater uniformity, in particular as regards the substrates disposed in the vicinity of the peripheral edge of the susceptor 9.

The jacket 37 is supported by a member 38 shaped as a hollow cylinder portion which rests on the lower wall 15. In this case, the jacket 37 and the member 38 are made in one piece.

The susceptor 9 is generally shaped as a disc. It is made from a thermally highly conductive material selected so as to withstand temperatures of more than 1300° C., to be compatible with the growth environments of III-V processes, to retain its integrity in highly reductive environments as is the case with dihydrogen and ammonia, and to have a thermal inertia which is as low as possible to enable its temperature rapidly to rise and fall during the various growth phases.

The susceptor 9 may, for instance, be made from graphite coated with silicon carbide such that the susceptor 9 has an increased resistance to chemical environments.

The susceptor 9 has one or a plurality of pockets 39 in the form of recesses provided on its upper surface.

During the growth process, the pockets 39 house the substrate(s).

Each pocket 39 has a depth greater than, and preferably substantially equal to, the thickness of the substrate used for growth.

The pockets 39 are preferably made prior to the operation to coat the susceptor 9 with silicon carbide.

FIG. 4 shows the heating device 11 in detail.

The heating device 11 comprises a flat heating element 41, in the form of a disc, disposed to face the susceptor 9 so as to heat the latter over its entire extent.

The heating element is disposed a few millimetres below the susceptor 9. This distance is selected in order to maximise the heating effect on the susceptor 9 while enabling the latter to rotate with no risk of contact with the fixed portions of the chamber 3.

This distance may be selected to be between 4 and 8 mm.

The heating element 41 is supplied by electrical current by connection plugs 45 which traverse the lower wall 15 of the chamber 3 via leak-tight passages 47 provided via said wall.

The electrical current supplying the heating element 41 is controlled by means of signals from instruments 23 (pyrometers) disposed above the upper wall 17 of the chamber 3 which read the temperature of the various substrates at various locations of the susceptor 9.

The locations concerned are typically in the vicinity of the centre of the susceptor 9, in the vicinity of a half-radius of the susceptor 9 and in the vicinity of the edge of said susceptor 9.

The controller of the heating element 41 is designed such that the temperature measured by the various pyrometers differs at most by 1° C. from a reference temperature of 1200° C.

Although a heating device 11 with only one heating element has been illustrated here, such a device could include two or more heating elements.

The heating device 11 could, for instance, comprise two flat heating elements, i.e. a central element, in the form of a disc, disposed to face a central portion of the susceptor 9 and a peripheral annular element disposed to heat the external crown of said susceptor 9.

As an alternative, the heating device 11 may comprise one or a plurality of rows of infrared lamps distributed radially beneath the susceptor 9. In this case, the heat from the lamps radiates over the susceptor 9. In order to screen the lamps from the ambient environment in the chamber 3, a transparent glass, made for instance from quartz, may be interposed between the lamps and the susceptor 9.

In this case, the heating element 41 extends radially beyond the peripheral edge of the susceptor 9. Losses of heat in the susceptor 9 are thus minimised and the uniform temperature of the whole of the surface of the susceptor 9 is promoted.

The heating element 41 may be made from pyrolytic graphite coated with silicon carbide SiC, pyrolytic boron nitride PBN, encapsulated graphite or from one or a plurality of other refractory materials such as, but not limited to, tungsten or uranium.

The convection restrictor, bearing reference numeral 49, is shown in FIG. 5 in particular.

The restrictor 49 chiefly comprises a flat disc 50 disposed above the susceptor 9 and below the upper wall 17 of the chamber 3.

The distance separating an inner surface 51 of the restrictor 49 from the upper surface of the susceptor 9 is such that a laminar flow is maintained along the path between the injector 5 and the collector 7. This limits the vertical convection gradient effect customarily due to the temperature difference between the susceptor 9 and the upper wall 17. This distance is typically between 20 and 50 mm.

The lower surface 51 of the disc 50 is disposed above the injectors connected to the upper supply lines 29-3, preferably at the level of these injectors. i.e., in this case, at the level of the upper edge of the passages 31 corresponding to these injectors.

The disc 50 has a diameter greater than and preferably substantially identical to the diameter of the susceptor 9.

The disc 50 may be made from a material identical to the material used for the production of the susceptor 9, for instance a graphite coated with silicon (SiC).

The disc 50 is supported by feet (not shown) bearing on the susceptor 9 in the vicinity of its periphery.

The convection restrictor 49 may be rotated jointly with the susceptor 9 during the growth process, for instance by means of a magnetic coupling with the device driving the susceptor-holder 25. The convection restrictor 49 may also be inserted in and removed from the chamber 3 jointly with the susceptor 9, in particular through the slot opening 21.

The disc 50 has a plurality of holes 53 corresponding to the windows of the chamber 3 to enable monitoring of the temperature of the substrate and the growth process by the optical instruments 23.

As an alternative, the disc 50 may be connected to the upper wall 17 of the chamber 3 such that it remains in position in said chamber even when the susceptor 9 is being inserted into or removed from the chamber 3.

In this case, the disc 50 is cleaned at the same time as the rest of the chamber 3 during routine maintenance operations.

During the growth process, the disc 50 reaches a temperature close to the temperature of the susceptor 9 and thus limits the temperature gradient between these two members. When the reaction gases flow between the susceptor 9 and the disc 50 they are subject to practically no natural convection.

This prevents the displacement of active ingredients in the region of the outlet edges and also prevents the condensation of the reaction gases in the upper portion of the chamber 3. This condensation generates, in conventional reactors, solid particles which may, when they fall on the substrate, degrade the properties of the film and the device. In any case, this condensation brings about inconsistencies in the growth process and is thus detrimental to the replicability of the process.

Although not shown, the reactor 1 may be connected to a system comprising a vacuum conveyor platform in order to convey the susceptor 9 between a loading station and the reactor 1 in reduced pressure conditions in a nitrogen and/or another inert gas environment.

An inventive reactor 1 has been described in that the injectors intended for the same gas are in particular arranged so as to lead into the chamber in the same plane and in a symmetrically distributed manner with respect to the same axis of symmetry of the susceptor 9 via one or a plurality of inlets.

The reactor 1 has been described with three sets of three supply lines each, each connected to two injectors.

It will be appreciated, however, that the reactor 1 is inventive in nature when two supply lines are each provided with an injector, these two injectors communicating with the chamber 3 one above the other and in an manner substantially parallel to the susceptor 9.

This inventive nature is not limited by the number of supply lines, the number of sub-sets of these supply lines, the number of supply lines included in a same sub-set or the number of injectors connected to the same supply line.

In this respect, the injection of a particular gas may take place by means of more or less than six injectors, although this number at present represents a particularly advantageous embodiment.

The number of supply lines intended for the same gas and/or the number of injectors connected to these lines may be selected in relation to the size of the susceptor 9. The larger the number of injectors, the more detailed the control of the process should be.

The reactor 1 is particularly suitable for operation with substrates whose size is between 2 and 4 inches. The invention is not, however, limited to such substrates.

The reactor 1 may be adapted, in terms of its shape and size in particular, as a function of the susceptor 9 which could, for instance, have a square, rectangular or other shape.

Although a plurality of injection passages 31 has been shown, it will be appreciated that all the injectors 30 of the injection device 5 could, in a variant, lead into the chamber 3 through a common inlet, or two inlets disposed symmetrically with respect to the axis 28 and each common to the injectors disposed on the same side of a vertical plane containing this axis 28.

The invention is not limited to the embodiments described above, but includes any variants which may be envisaged by a person skilled in the art.

1. A reactor (1) comprising:
a chamber (3) having a lower wall (15), an upper wall (17) and a side wall (19) connecting the lower wall (15) to the upper wall (17);
a support plate (9) for one or more substrate elements which is mounted inside the chamber (3);
at least one first supply line (29-1) for a first type of gas, and at least one second supply line (29-2), separate from the first supply line, for a second type of gas;
a gas injection device (5) and a gas collector (7); characterized in that:
the gas injection device (5) includes at least one injector connected to the first supply line (29-1) and at least one injector (30) connected to the second supply line (29-2), said injectors leading into the chamber (3) through at least one inlet (31) provided in the side wall (19);
all of the injectors (30) of the first supply line (29-1) and all of the injectors of the second supply line (29-2) lead into the chamber one above the other;
the collector (7) includes at least one outlet provided in the side wall (19) at a location opposite said inlet (31) relative to the support plate (9) and substantially at the level of said inlet (31).

2. A reactor according to claim 1, further comprising at least one third supply line (29-3) for a third type of gas, wherein the gas injection device (5) comprises at least one injector (30) connected to the third supply line (29-3) and leading into the chamber (3) through at least one inlet (31) in the side wall (19), the injector(s) (30) of the third supply line (29-3) leading into the chamber above the injectors (30) connected to the first supply line (29-1) and above the injectors (30) connected to the second supply line (29-2) in a manner generally parallel to the support plate (9).

3. A reactor according to claim 1, wherein the injectors lead into the chamber in a manner substantially parallel to the support plate (9).

4. A reactor according to claim 1, wherein the inlet(s) (31) at the lowest level with respect to the support plate (9) are disposed at a height with respect to the support plate (9) determined as a function of the thickness of the substrate element(s) such that the inlets lead into the chamber at the level of the upper surface of said substrate elements.

5. A reactor according to claim 1, wherein the injection device (5) comprises a plurality of injectors (30) connected to a common supply line (29) and generally leading into the chamber in the same plane, parallel to the plane of the support plate (9).

6. A reactor according to claim 1, wherein each injector (30) leads into the chamber (3) via a respective inlet (31).

7. A reactor according to claim 1, wherein each inlet (31) has a generally plane overall shape and extends in a plane parallel to the plane of the support plate (9).

8. A reactor according to claim 1, wherein each inlet (31) of the first supply line (29-1) is above an inlet (31) of the second supply line (29-2).

9. A reactor according to claim 1, wherein the injectors (30) and/or the inlets (31) corresponding to the same supply line (29) are arranged in a mutually symmetrical manner with respect to a common axis (28) passing above the support plate (9) and through the outlet (33) of the collector.

10. A reactor according to claim 1, comprising at least one additional supply line (29) for the gas of the first type, the second type or the third type, wherein the injection device (5) comprises at least one injector (30) connected to the additional supply line which leads into the chamber in the same plane as the injector(s) connected to the first or the second supply line.

11. A reactor according to claim 9, wherein the axis (28) common to the injectors (30) and/or inlets (31) of the first supply line (29-1) coincides with the axis common to the injectors (30) and/or inlets (31) of the second supply line (29-2) in respective planes parallel to one another.

12. A reactor according to claim 1, wherein each supply line is connected to a respective flow controller.

13. A reactor according to claim 1, wherein the support plate (9) is supported by a plate-holder (25) able to rotate with respect to the chamber (3) about an axis extending heightwise in the chamber (3).

14. A reactor according to claim 1, further comprising a cylindrical member (50) whose section corresponds in shape to the support plate (9) and is disposed above said support plate (9) as a convection restrictor (49).

15. A reactor according to claim 1, further comprising a jacket (37) shaped so as to fill the space between the side wall (19) of the chamber (3) and the support plate (9) and, in terms of height, flush with the height of the substrate(s).

16. A reactor according to claim 1, further comprising a heating device (11) for the support plate (9) disposed below said plate and having a corresponding shape.

17. A reactor according to claim 1, wherein the side wall (19) has a contour whose shape corresponds to the contour of the support plate (9) and the inlets (29) are each transversely shaped as a section of said side wall (19).

18. A reactor according to claim 1, wherein the support plate (9) has a circular development and wherein each inlet (31) extends as an angular sector centred on said support plate (9).

19. A reactor according to claim 1, wherein the lower wall (15), the upper wall (17) and the side wall (19) are each at least partially lined by an outer wall (15B, 17B, 19B) of similar shape, and fluid circulation ducts are provided between each wall of the chamber (3) and its respective outer wall.

20. A reactor according to claim 1, wherein the collector (7) has one or a plurality of outlets (33) disposed symmetrically with respect to the inlets of the injection device with respect to the support plate (9) and at the level of said inlets.
